(19) United States
(12) Patent Application Publication
(10) Pub. No.: US 2026/0194568 A1
(43) Pub. Date: Jul. 9, 2026

(54) APPARATUS AND METHOD FOR DETECTING AN ARC FAULT

(71) Applicant: Landis+Gyr Technology, Inc., Alpharetta, GA (US)

(72) Inventors: Daniel E. FABREGA, Alpharetta, GA (US); Anthony J. BESETT, Sebeka, MN (US)

(21) Appl. No.: 19/129,505

(22) PCT Filed: Dec. 19, 2023
(86) PCT No.: PCT/US2023/084889

§ 371 Date: May 13, 2025

(30) Foreign Application Priority Data
Dec. 29, 2022 (GB) 2219811.3

(51) Int. Cl. G01R 31/12; G01R 22/06

(52) U.S. Cl. CPC G01R 31/1272; G01R 22/063; G01R 22/068

(57) ABSTRACT

An apparatus (100) for detecting an arc fault produced by a power line (130, 135, 230, 235) is disclosed. The apparatus comprises an antenna (105, 205) for disposal in a near-field of at least one power line. The apparatus also comprises a receiver (215) coupled to the antenna; and processing circuitry (115, 260) coupled to the receiver and configured to identify an arc fault based on a signal received from the receiver. Also disclosed is a corresponding method of detecting an arc fault produced by a power line.

### FIELD OF INVENTION

The disclosure is in the field of methods and apparatuses for detecting an arc fault produced by a power line, and relates in particular to an electricity meter comprising such an apparatus for detecting an arc fault

### BACKGROUND

An arc fault is a high power discharge of electricity between two or more conductors. Such a discharge may generate very high temperatures and may ignite combustible materials, triggering an electrical fire. As such, arc faults produced by residential and commercial power lines have the potential to cause enormous damage, and pose a major safety risk.

Arc faults can range in current from a few amps up to several thousand amps, and may be variable in duration.

Arc faults may be categorized into three main categories: ground arc fault; parallel arc fault; and series arc fault.

Parallel and ground arc faults are usually caused by short circuits between power lines, which have higher current magnitude. As such, known short-circuit breakers or fuses may effectively detect arc faults and provide adequate protection.

A current magnitude of a series arc fault may be limited by the load in a circuit. The current in a series arc fault may generally be the same as the normal working current, or even slightly smaller, and its frequency spectrum characteristics are generally concentrated in the frequency band of 2 kHz to 20 MHz.

As a result, known circuit breakers may not provide reliable protection. This is because known circuit breakers may not respond fast enough to a sudden series arc fault, due to its lower current magnitude and/or its high frequency bandwidth.

In some territories, some degree of arc fault detection may be mandated by legislation. For example, in the United States of America, the National Electrical Code (NEC) comprises provisions for arc fault detection.

Current solutions for implementing arc fault detection may involve the use of a current transformer (CT) or Hall Effect sensors. However, a drawback to such approaches is their limited frequency bandwidth, which may be limited to a maximum of about 200 KHz. As stated above, a typical series arc fault may have frequency components up to and even higher than 20 MHz.

It is therefore desirable to provide a relatively low-complexity, reliable and effective method and apparatus for detecting arc faults within the above frequency band.

Furthermore, it is desirable that such arc fault detection may be integrated with an electricity meter. As such, it is required that such arc fault detection may be implemented without interfering with collocated transceivers and/or circuitry within the Electricity Meter.

It is therefore an aim of at least one embodiment of at least one aspect of the present disclosure to obviate or at least mitigate at least one of the above identified shortcomings of the prior art.

### SUMMARY OF INVENTION

The present disclosure is in the field of methods and apparatuses for detecting an arc fault produced by a power line, and relates in particular to an electricity meter comprising such an apparatus for detecting an arc fault. According to a first aspect of the disclosure, there is provided an apparatus for detecting an arc fault produced by a power line. The apparatus comprises an antenna. The antenna may be for disposal in a near-field of at least one power line. The apparatus comprises a receiver coupled to the antenna. The apparatus comprises processing circuitry coupled to the receiver. The processing circuitry may be configured to identify an arc fault, e.g. an arc fault produced by the at least one power line, based on a signal received from the receiver.

Advantageously, such an apparatus provides a relatively low-complexity, reliable and effective means for detecting arc faults.

Furthermore, such a solution may be implemented without interfering with collocated transceivers and circuitry within an electricity meter, as described in more detail below. That is, the use of such an antenna effectively provides a relatively non-invasive series arc fault current detection sensor. The described antenna may function as a near-field magnetic pick-up, and may produce a detectable and measureable current proportional to its magnetic field. Advantageously, use of such an antenna minimizes interference to and from adjacent transceivers within the immediate vicinity of the antenna, e.g. within an electricity meter, thereby avoiding receiver desensitization, as described in more detail below.

The near field of the at least one power line may be immediately adjacent the at least one power line. The antenna may be for disposing adjacent the at least one power line such that a magnetic field induced by an arc fault in the power line may induce a flow of current in the antenna.

The antenna may provide a near-field magnetic pick-up. That is, the antenna when disposed in the near-field of the at least one power line may function as a near-field magnetic pick-up.

The disclosed apparatus may provide an accurate, reliable, and low-cost solution, while also minimizing/negating its impact to other collocated radios, and vice versa.

Furthermore, the disclosed apparatus may mitigate a requirement to implement other more complex and/or expensive solutions for series arc fault detection, such as solutions involving the use of a current transformer (CT) or Hall Effect sensors.

The antenna may comprises a coil antenna. The coil antenna may comprise a plurality of turns.

A magnitude of the current induced in the antenna may be substantially proportional to a quantity of turns provided in the antenna. As such, more turns may be added to the antenna. An amount of turns in the antenna may be limited by an available space within a PCB upon which the antenna may be implemented.

The antenna may comprise a planar antenna.

That is, the antenna may be formed in a metal layer of a PCB, and thus may be substantially planar. Advantageously, such a planar antenna, e.g. a planar coil, minimizes interference with other transceivers and/or high frequency circuitry in the vicinity of the antenna, yet while also providing adequate sensitivity to detect arc faults.

The antenna may be provided on one or more metal layers of a printed circuit board (PCB).

For example, the antenna may be provided on a top layer of the PCB, as close as possible to the at least one power line. The antenna may be provided on a plurality of layers of the PCB, thereby increasing an overall number of turns of the antenna, and thus improving a sensitivity of the antenna.

The receiver may be configured to receive signals in the frequency range of at least 2 kHz to 20 MHz.

A series arc fault may typically exhibit frequency spectrum characteristics concentrated in the frequency band of 2 kHz to 20 MHz. As such, said receiver may be optimized for detection of arc faults.

Furthermore, the disclosed apparatus may mitigate a requirement to implement more complex and/or expensive solutions for series arc fault detection, such as solutions involving the use of a current transformer (CT) or Hall Effect sensors, wherein a technical drawback of such prior art approaches is their limited frequency bandwidth, which may be limited to about 200 KHz.

The receiver may be a broadband receiver.

The processing circuitry may be configured to identify peaks in the signal.

In some examples, the processing circuitry may comprise one of more digital signal processors (DSPs), and/or processors configured to execute DSP routines.

The processing circuitry may be configured to analyze a signal based on the peaks to identify and/or characterize an arc fault.

That is, the processing circuitry may be configured to distinguish a signal generated by an arc fault from general noise and/or other signals.

The processing circuitry may comprise an amplifier configured to amplify a current provided by the antenna.

The processing circuitry may comprise a peak-detector circuit for demodulating an output of the receiver.

The processing circuitry may comprise a comparator for conditioning an output of the peak detector circuit.

The processing circuitry may comprise at least one processor configured to analyze the output of the comparator to identify an arc fault.

In an example, the antenna may function as a near-field magnetic pick-up. The antenna may produce a current proportional to its magnetic field. That is, a current induced in the antenna by a signal caused by an arc fault on the at least one power line may be proportional to its magnetic field. That current may be amplified by the receiver. The receiver may be provided with sufficient gain to amplify the current. An output of the receiver may be demodulated via a peak detector to provide a peak-detected signal. The peak-detected signal may undergo signal conditioning via a comparator. The comparator may produce pulses based on an arc fault signature. Said pulses may be analyzed by a/the processing circuitry, e.g. by a metrology microprocessor. Such analysis may be by way of an algorithm, such as a proprietary algorithm. Said algorithm may be selected/configured to reliably detect arc faults.

The apparatus may comprise the at least one power line.

The at least one power line may be electrically isolated from the antenna.

The at least one power line extend across the antenna in a plane substantially parallel to a plane defined by the antenna.

The at least one power line may extend across the antenna in a plane substantially parallel to a plane defined by the antenna. The receiver may be relatively close to the antenna, thus maximizing its sensitivity. This technique may also mitigate interference generated by the other radiation sources, e.g. other radios, while minimizing re-radiation coming from the antenna.

The near-field may be an inductive near field.

According to a second aspect of the disclosure, there is provided an electricity meter comprising the apparatus according to the first aspect.

The processing circuitry may also be configured as a metrology processor.

That is, the processing circuitry may be configured for metering consumption of electrical power based on current and/or voltage measurements of the at least one power line.

The electricity meter may comprise a sub-gigahertz radio. The electricity meter may comprise a Bluetooth radio. The electricity meter may comprise a Wi-Fi radio. The electricity meter may comprise a ZigBee radio. The electricity meter may comprise one or more DC-to-DC converters.

The antenna may be formed on a same substrate as the processing circuitry.

Advantageously, by implementing the antenna as a planar antenna on a plane defined by the substrate, e.g. PCB, interference between the antenna and other radios or transceivers may be limited.

That is, the disclosed arc fault detection solution may be suitable for implementation within a “Smart Electric Meter”, e.g. a meter having communications functionality. The disclosed antenna solution may be suitable for operation alongside collocated potential interferers such as ZigBee, Wi-Fi and/or Sub-Gigahertz radio, microprocessors and/or one or more DC-to-DC converters. Implementation of a relatively low-profile planar PCB coil antenna may limit the potential interferers from reducing the arc detection receiver sensitivity and vice-versa.

In response to detection of an arc fault, the processing circuitry may be configured to transmit a message indicating occurrence of an arc fault.

In response to detection of an arc fault, the processing circuitry may be configured to isolate a power supply to the at least one power line.

For example, the processing circuitry may be configured to trigger a service disconnect switch as a safety measure, to isolate the at least one power line from a load.

According to a third aspect of the disclosure, there is provided a method of detecting an arc fault produced by a power line. The method comprises disposing an antenna in the near-field of at least one power line, wherein the antenna is coupled to a receiver and processing circuitry is coupled to the receiver and configured to identify an arc fault based on a signal received from the receiver.

The above summary is intended to be merely exemplary and non-limiting. The disclosure includes one or more corresponding aspects, embodiments or features in isolation or in various combinations whether or not specifically stated (including claimed) in that combination or in isolation. It should be understood that features defined above in accordance with any aspect of the present disclosure or below relating to any specific embodiment of the disclosure may be utilized, either alone or in combination with any other defined feature, in any other aspect or embodiment or to form a further aspect or embodiment of the disclosure.

### BRIEF DESCRIPTION OF DRAWINGS

These and other aspects of the present disclosure will now be described, by way of example only, with reference to the accompanying drawings, wherein:

FIG. 1a depicts a photograph of a top surface of an example apparatus comprising an antenna, according an embodiment of the disclosure;

FIG. 1b depicts a photograph of a bottom surface of an example apparatus comprising an antenna, according an embodiment of the disclosure;

FIG. 2 depicts a further example of an apparatus comprising an antenna, according an embodiment of the disclosure; and

FIG. 3 depicts a block diagram of an example electricity meter, according to according an embodiment of the disclosure.

### DETAILED DESCRIPTION OF DRAWINGS

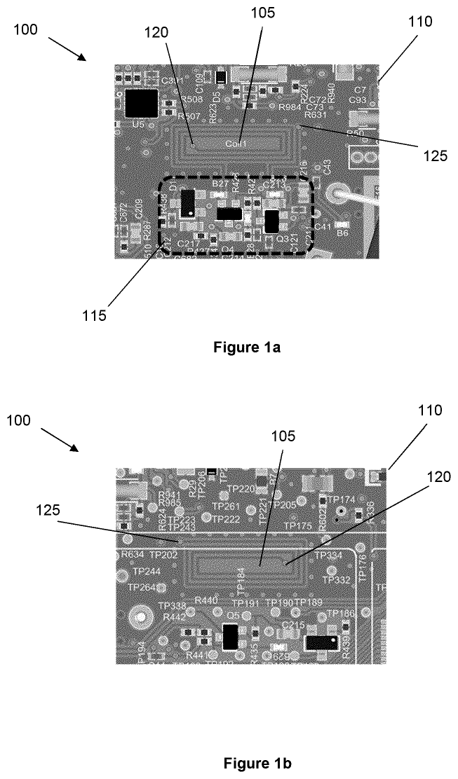

FIG. 1a depicts a portion of a photograph of a top surface of an example apparatus 100 comprising an antenna 105, according an embodiment of the disclosure. FIG. 1b depicts a portion of a photograph of a bottom surface of the example apparatus 100.

The apparatus 100 may be suitable for detecting an arc fault produced by a power line, as will be described in more detail below.

The example apparatus 100 comprises a substrate 110, which in the depicted example is a printed circuit board (PCB).

The antenna 105 is formed on the substrate 110. That is, the antenna 105 is implemented as a planar antenna 105. The antenna 105 does not protrude from a surface of the substrate 110. The antenna 105 is not formed as a discrete component that is mounted on the substrate 110. Instead, the antenna is formed on, or within a layer of, the substrate 110. Advantageously, such a planar antenna, e.g. a planar coil, minimizes interference with other transceivers and/or high frequency circuitry in the vicinity of the antenna 105, yet while also providing adequate sensitivity to detect arc faults.

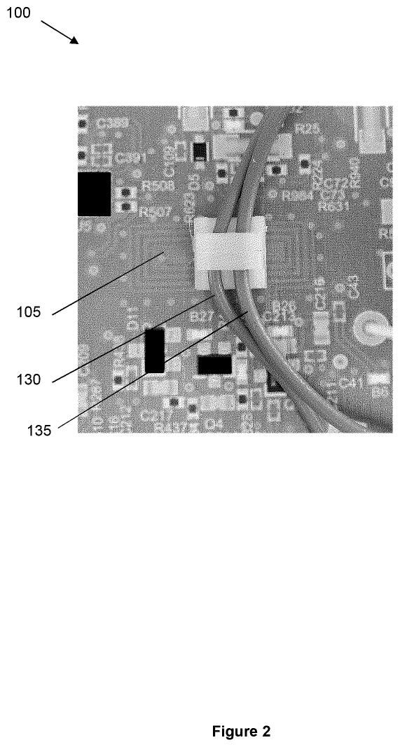

The antenna 105 may function as a near-field magnetic pick-up. That is, the antenna 105, when disposed in the near-field of at least one power line, may function as a near-field magnetic pick-up, as described in more detail below with reference to FIG. 2.

The example antenna 105 is implemented as a coil antenna, comprising a plurality of turns. Although in the example depicted in FIG. 1 only four turns are depicted, it will be understood that in other embodiments the antenna 105 may be implemented with fewer than or greater than four turns. A magnitude of the current induced in the antenna 105 may be substantially proportional to a quantity of turns provided in the antenna 105. As such, more turns may be added to the antenna 105 which may, for example, be limited by an available space within the substrate 110.

Similarly, the example antenna 105 is substantially elongate in shape, with each turn corresponding to a substantially rectangular shape. It will also be appreciated that other shapes, such as square or polygonal, may be implemented.

In a preferred example, at least a portion of the antenna 105 is implemented on an upper metal layer of the substrate 110, at or close to the surface, thereby minimizing a distance and/or shielding between the antenna 105 and one or more power lines that may be disposed relatively close to the substrate.

In the example it can be seen that a first layer of the antenna 105 is implemented on the upper metal layer of the substrate 110 depicted in FIG. 1a and a second layer of the antenna 105 is implemented on a lower metal layer of the substrate 110. A first via 120 and a second via 125 connect first layer of the antenna 105 to the second layer of the antenna 105. By implementing the antenna 105 on a plurality of layers of the substrate 110, an overall number of turns of the antenna 105 may be increased within an available space, thereby improving a sensitivity of the antenna 105.

In some examples, a ground shield and/or power plane may be implemented in the substrate, such that the ground shield and/or power plane extends at least partway around the antenna 105, thereby minimizing potential interference between the antenna 105 and surrounding circuitry and/or components.

The apparatus 100 also comprises circuitry 115. The example circuitry 115 comprises processing circuitry and a receiver coupled to the processing circuitry.

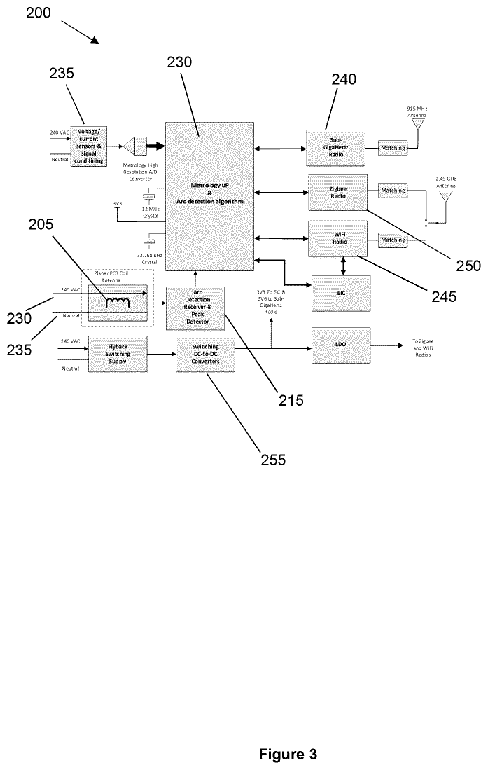

In the depicted example, the circuitry 115 comprises various discrete components, e.g. resistors, comparators, and the like. It will be appreciated that the circuitry 115 is provided for purposes of example only, and in other embodiments the circuitry 115 may comprise one or more integrated circuits. The circuitry 115 may be configured to identify an arc fault, e.g. an arc fault produced by at least one power line, based on a signal received from the receiver. The receiver may be configured to receive signals in the frequency range of at least 2 kHz to 20 MHz. A further example of the circuitry is provided in FIG. 3 below. As shown, the receiver circuit is relatively close to the antenna 105, thus maximizing its sensitivity.

FIG. 2 depicts a further example of the apparatus 100 comprising the antenna 105, according an embodiment of the disclosure. In the example of FIG. 2, a first power line 130 and a second power line 135 are depicted.

The first power line 130 and/or the second power line 135 may be an alternating current power supply lines, such as power supply lines that may be metered by an electricity meter.

In an example, the first power line 130 is a neutral line and the second power line 135 corresponds to one phase of a power supply, such as a 120 volt or 240 volt, 50 Hz or 60 Hz alternating current power supply.

In the example in FIG. 3, the power lines 130, 135 extend across the antenna 105 in a plane substantially parallel to a plane defined by the antenna 105. Although the power lines 130, 135 are depicted as attached to the substrate 110 using a fastener, in other examples the power lines 130, 135 may be adhered to, or even embedded within, the substrate.

The antenna 105 is disposed in an inductive near-field of the power lines 130, 135 for a signal in the range of 20 kHz to 20 MHz that may be generated by an arc fault event on said power lines 130, 135.

The power lines 130, 135 are provided sufficiently close to the antenna 105 such that the disclosed antenna 105 may function as a near-field magnetic pick-up, and may produce a detectable and measureable current substantially proportional to its magnetic field. As described such current below, a may be received/amplified/processed by a receiver and processing circuitry.

FIG. 3 depicts a block diagram of an example electricity meter 200, according to according an embodiment of the disclosure.

The electricity meter 200 comprises an antenna 205, which may generally correspond to the antenna 105 of the example embodiments of FIGS. 1a to 2. That is, the antenna 205 may be a planar, coil antenna. Also depicted is a first power line 230 and a second power line 235 extending over the antenna 205. As described above, the antenna may function as a near-field magnetic pick-up to the first power line 230 and a second power line 235 extending over the antenna 205.

An arc detection receiver and peak detector circuit 215 is depicted. In an example, such a circuit 215 may comprise at least some of: an amplifier configured to amplify a current provided by the antenna; a peak-detector circuit for demodulating an output of the receiver and a comparator for conditioning an output of the peak detector circuit.

An output of the arc detection receiver and peak detector circuit 215 is provided to processing circuitry 230. The processing circuitry 260 may be configured to analyze the output of the comparator to identify an arc fault. In some embodiments, the processing circuitry may also be configured as a metrology processor, for metering consumption of electricity using a voltage and/or current sensing and signal conditioning circuit 235. In other examples, a separate processor may be provided for arc fault detection.

For purposes of example, various sources of potential interference that may be components of the electricity meter 200 are also depicted. For example, a sub-gigahertz radio 240 is depicted. In examples, the sub-gigahertz radio may be configured to receive and transmit a signal at a 915 MHz band. Also depicted is a “Wi-Fi” radio 245, e.g. a radio conforming to IEEE 802.11, and a “ZigBee” radio 250, e.g. a radio conforming to IEEE 802.11. It will be understood that these are just examples, and in other examples further or alternative communications means may be implemented, such as a Bluetooth radio conforming to IEEE 802.15.1, or the like. Other potential interference sources include various power supplies, such as a switching supply with DC-to-DC converters 255.

Advantageously, because the antenna 205 is implemented as a planar antenna 205 that does not extend of protrude from the PCB, said antenna 205 may function as a near-field magnetic pick-up to the power lines 230, 235, and may produce a detectable and measureable current proportional to its magnetic field. Advantageously, use of such an antenna 205 minimizes interference to and from adjacent transceivers within the immediate vicinity of the antenna, e.g. gigahertz radio 240, “Wi-Fi” radio 245 and “ZigBee” radio 250, thereby avoiding receiver desensitization.

Although the disclosure has been described in terms of particular embodiments as set forth above, it should be understood that these embodiments are illustrative only and that the claims are not limited to those embodiments. Those skilled in the art will be able to make modifications and alternatives in view of the disclosure, which are contemplated as falling within the scope of the appended claims. Each feature disclosed or illustrated in the present specification may be incorporated in any embodiments, whether alone or in any appropriate combination with any other feature disclosed or illustrated herein.

### REFERENCE NUMERALS

| | | | |
|---|---|---|---|
| 100 | apparatus | 215 | receiver and peak detector |
| 105 | antenna | | circuit |
| 110 | substrate | 230 | first power line |
| 115 | circuitry | 235 | second power line |
| 120 | first via | 240 | gigahertz radio |
| 125 | second via | 245 | Wi-Fi radio |
| 130 | first power line | 250 | ZigBee radio |
| 135 | second power line | 255 | DC-to-DC converters 250 |
| 200 | electricity meter | 260 | processing circuitry |
| 205 | antenna | | |

1. An apparatus (100) for detecting an arc fault produced by a power line (130, 135, 230, 235), the apparatus comprising:
an antenna (105, 205) for disposal in a near-field of at least one power line;
a receiver (215) coupled to the antenna; and
processing circuitry (115, 260) coupled to the receiver and configured to identify an arc fault based on a signal received from the receiver.

2. The apparatus (100) of claim 1, wherein the antenna (105, 205) comprises a coil antenna comprising a plurality of turns.

3. The apparatus (100) of claim 1, wherein the antenna (105, 205) comprises a planar antenna.

4. The apparatus (100) of claim 1, wherein the antenna (105, 205) is provided on one or more metal layers of a printed circuit board (PCB).

5. The apparatus (100) of claim 1, wherein the receiver (215) is configured to receive signals in the frequency range of at least 2 kHz to 20 MHz.

6. The apparatus (100) of claim 1, wherein the processing circuitry (115, 260) is configured to:
identify peaks in the signal; and
analyze a signal based on the peaks to identify and/or characterize an arc fault.

7. The apparatus (100) of claim 1, wherein the processing circuitry (115, 260) comprises:
an amplifier configured to amplify a current provided by the antenna (105, 205);
a peak-detector circuit for demodulating an output of the receiver (215);
a comparator for conditioning an output of the peak detector circuit; and
at least one processor (230) configured to analyze the output of the comparator to identify an arc fault.

8. The apparatus (100) of claim 1, comprising the at least one power line (130, 135, 230, 235), wherein:
the at least one power line is electrically isolated from the antenna (105, 205); and
the at least one power line extends across the antenna in a plane substantially parallel to a plane defined by the antenna.

9. The apparatus (100) of claim 1, wherein the near-field is an inductive near field.

10. An electricity meter (200) comprising the apparatus of claim 1.

11. The electricity meter (200) of claim 10, wherein the processing circuitry (115, 260) is also configured as a metrology processor.

12. The electricity meter (200) of claim 10, comprising at least one of:
a sub-gigahertz radio (240);
a Bluetooth radio;
a Wi-Fi radio (245); and/or
a ZigBee radio (250).

13. The electricity meter (200) of claim 10, wherein the antenna (105, 205) is formed on a same substrate as the processing circuitry (115, 260).

14. The electricity meter (200) of claim 10 wherein, in response to detection of an arc fault, the processing circuitry (115, 260) is configured to:
transmit a message indicating occurrence of an arc fault; and/or
isolate a power supply to the at least one power line (130, 135, 230, 235).

15. A method of detecting an arc fault produced by a power line (130, 135, 230, 235), the method comprising disposing an antenna (105, 205) in the near-field of at least one power line, wherein the antenna is coupled to a receiver (215) and processing circuitry (115, 260) is coupled to the receiver and configured to identify an arc fault based on a signal received from the receiver.
